(19) United States
(12) Patent Application Publication
(10) Pub. No.: US 2011/0235274 A1
(43) Pub. Date: Sep. 29, 2011

(54) HOUSING AND ELECTRONIC DEVICE USING SAME

(75) Inventors: CHANG-HAI GU, Shenzhen City (CN); PO-FENG HO, Shindian (TW)

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/948,868

(22) Filed: Nov. 18, 2010

(30) Foreign Application Priority Data
Mar. 26, 2010 (CN) 201010133529.2

(51) Int. Cl. H05K 7/20; A47B 96/00; H05K 7/00

(52) U.S. Cl. 361/692; 312/237; 361/679.01; 361/690

(57) ABSTRACT

A housing includes a main body defining a window and at least one glue injecting hole near the window. A screen guard covering the window, defines a slit between the main body and the screen guard. A glue layer located in the slit adheres the screen guard to the main body, wherein the at least one glue injecting hole communicates with the window. The glue layer is formed by injecting glue into the slit from at least one glue injecting hole.

### BACKGROUND

1. Technical Field

The disclosure generally relates to housings, particularly to housings used in electronic devices.

2. Description of Related Art

Many housings for electronic devices include a main body and a transparent screen guard. The main body and the screen guard are manufactured in separate molding processes and glued or fixed together by other means. Over time, the glue or other means may wear and allow dust and moisture to enter the housing, potentially damaging the electronic elements inside. Furthermore, because the main body and the screen guard are made in two separate processes and then connected in a separate step, assembly time is long and complicated, making manufacturing burdensome.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary housing used in an electronic device. Moreover, in the drawings like reference numerals designate corresponding parts throughout the several views. Wherever possible, the same reference numbers are used throughout the drawings to refer to the same or like elements of an embodiment.

FIG. 1 is an isometric view of an embodiment of a housing including a main body and a screen guard.

FIG. 2 is another isometric view of the housing in FIG. 1 shown in another aspect.

FIG. 3 is a cross-sectional view of the housing in FIG. 2 along the line

FIG. 4 is a cross-sectional view of an insertion of glue into the housing in FIG. 3.

### DETAILED DESCRIPTION

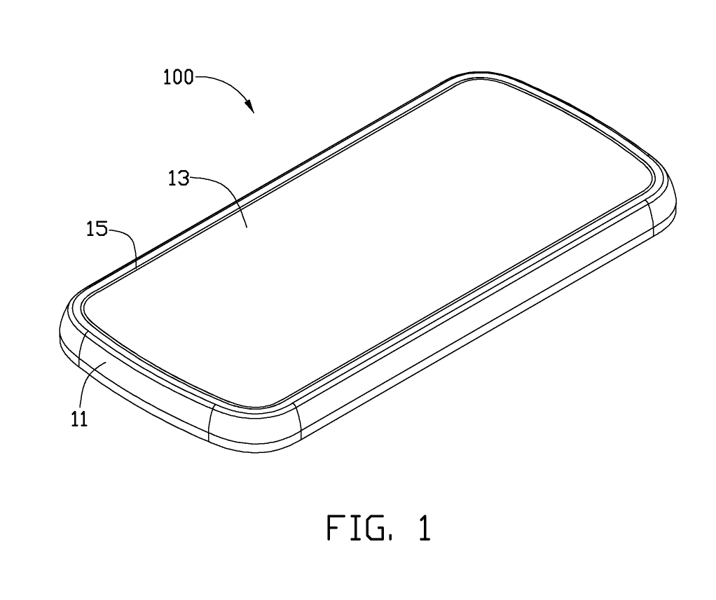

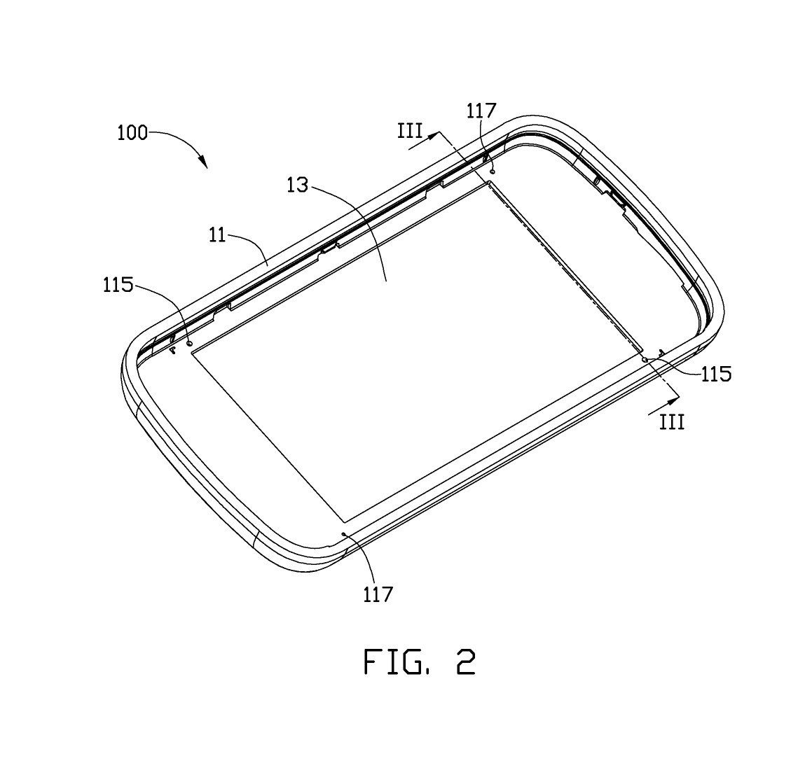

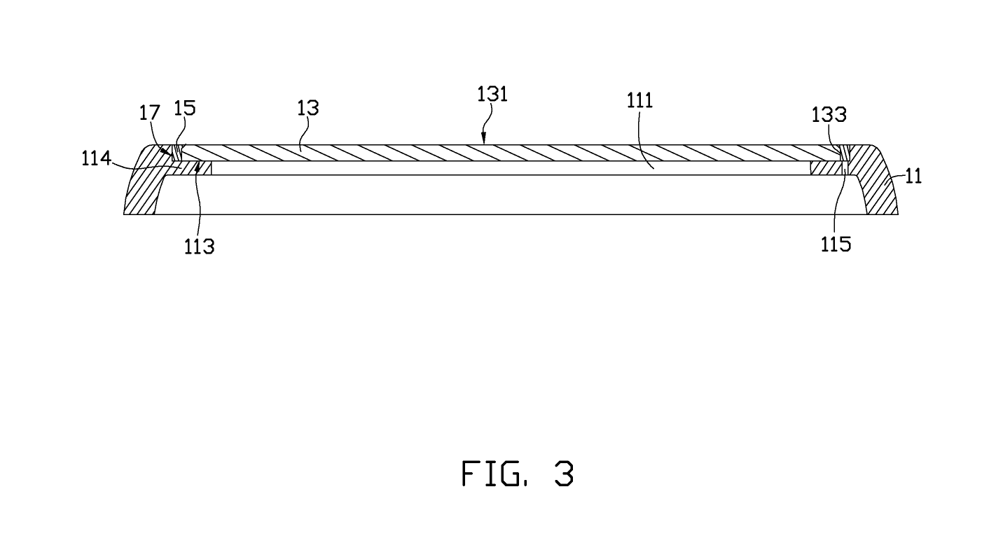

FIGS. 1 through 3 show a portion of an electronic device 100, such as a mobile phone. The electronic device 100 includes a housing (not labeled). The housing includes a main body 11, a screen guard 13 mounted to the main body 11, and a glue layer 15. The screen guard 13 is adhered to the main body 11 with glue. The glue layer 15 is formed between the screen guard 13 and the main body 11 by injecting the glue between the screen guard 13 and the main body 11. The main body 11 may be molded from a thermoplastic material that has good compact resistance and good scratch resistance, such as Polycarbonate (PC), Polymethyl Methacrylate (PMMA), Polyamide (PA), or any combination thereof.

The main body 11 defines a window 111 in an inner surface and a receiving space 113 in an outer surface for receiving the screen guard 13. The window 111 communicates with and is adjacent to the receiving space 113. The receiving space 113 is larger than the window 111, thus a flange 114 is formed in the main body and around the window 111. The flange 114 supports the screen guard 13 when the screen guard 13 is accommodated in the receiving space 113. The flange 114 defines a number of glue injecting holes 115 and an equal number of air holes 117. In this embodiment, there are two glue injecting holes 115 and two air holes 117. The glue injecting holes 115 are respectively defined near opposite corners of the window 111 and the air holes 117 are respectively defined near the other opposite corners of the window 111. In this embodiment, each glue injecting hole 115 is substantially circular and has a diameter ranging from about 0.5 millimeter to about 1.0 millimeter, and each air hole 117 is substantially circular and has a diameter about 0.5 millimeter.

The screen guard 13 is transparent and includes an exterior surface 131 and a peripheral surface 133. When the screen guard 13 is located in the receiving space 113, a slit 17 is defined between the peripheral surface 133 and the main body 11 in the receiving space 113. The glue injecting holes 115 and the air holes 117 communicate with the slit 17 so that the glue can be injected into the slit 17. The glue layer 15 is formed by injecting the glue into the slit 17. The glue layer 15 is leveled with the outer surface of the housing so that the outer surface of the housing is smooth.

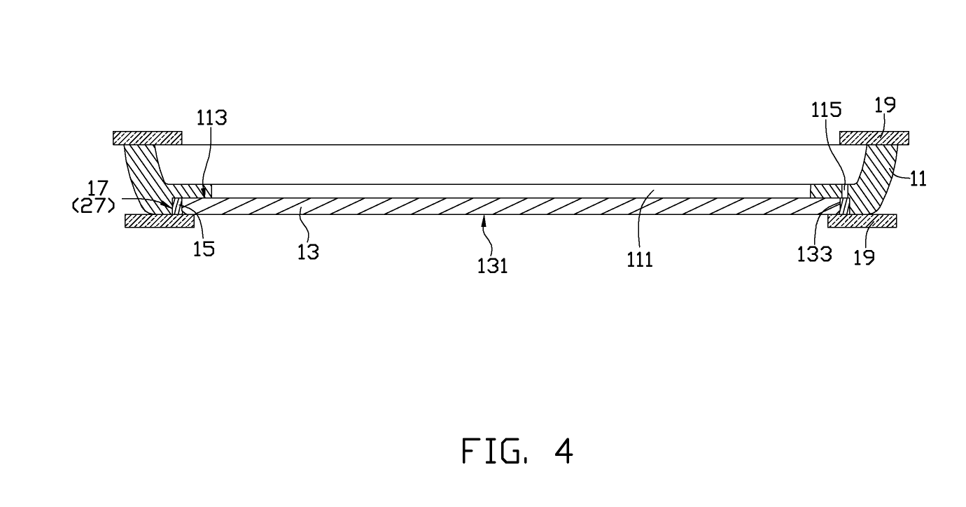

The glue layer 15 may be formed by injecting an ultraviolet curing glue into the slit 17. In this embodiment, the ultraviolet curing glue is mainly comprised of polymethyl methacrylate. Referring to FIG. 4, to inject the ultraviolet curing glue into the slit 17, the housing is held by two opposite plates 19 with one of the plates 19 positioned on the exterior surface 131 to cover the slit 17. Thus, a channel 27 is defined among the housing, the window 111 and the plate 19 positioned on the exterior surface 131. The ultraviolet curing glue is then injected into the channel 27 from the glue injecting holes 115 under twice the atmospheric pressure, until the ultraviolet curing glue flows out of the air holes 117. During this stage, the air in the channel 27 can escape from the air holes 117 to prevent pores from generating in the glue layer 15. The ultraviolet curing glue in the channel 27 is then cooled to form the glue layer 15 between the main body 11 and the screen guard 13 to adhere the screen guard 13 to the main body 11. The plate 19 positioned on the exterior surface 131 may further include transparent oil opposing the channel 27 to prevent the glue layer 15 from adhering to the one of the plates 19 positioned on the exterior surface 131.

The glue layer 15 may also be made of a hot setting glue, such as epoxy resin glue. In this case, the hot setting glue is first put in the slit 17 and then heated to form the glue layer 15 between the main body 11 and the screen guard 13 to adhere the screen guard 13 to the main body 11.

It is to be understood, however, that even through numerous characteristics and advantages of the disclosure have been set forth in the foregoing description, together with details of the system and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A housing comprising:
a main body defining a window therein and at least one glue injecting hole near the window;
a screen guard covering the window to define a slit between the main body and the screen guard; and
a glue layer located in the slit to adhere the screen guard to the main body;
wherein the at least one glue injecting hole communicates with the window, and the glue layer is formed by injecting glue into the slit from each glue injecting hole.

2. The housing of claim 1, wherein the window is defined in an inner surface of the main body, the main body further comprises a receiving space defined in an outer surface thereof, and the screen guard is accommodated in the receiving space.

3. The housing of claim 2, wherein the window communicates with the receiving space; the receiving space is larger than the window, thus a flange 114 is formed in the main body around the window; the flange supports the screen guard when the screen guard is accommodated in the receiving space.

4. The housing of claim 3, wherein the at least one glue injecting hole is defined in the flange.

5. The housing of claim 4, further comprising at least one air hole defined in the flange, the at least one air hole communicating with the slit thereby allowing air to escape from the slit.

6. The housing of claim 5, wherein there are two glue injecting holes and two air holes; the glue injecting holes are respectively defined near opposite corners of the window and the air holes are respectively defined near another opposite corners of the window.

7. The housing of claim 5, wherein the at least one glue injecting hole is substantially circular and has a diameter ranging from about 0.5 millimeter to about 1.0 millimeter.

8. The housing of claim 5, wherein the at least one air hole is substantially circular and has a diameter of about 0.5 millimeter.

9. The housing of claim 1, wherein the screen guard comprises an exterior surface and a peripheral surface, and the slit is defined between the peripheral surface and the main body in the receiving space.

10. The housing of claim 9, wherein the glue layer is leveled with the outer surface of the housing such that the outer surface of the housing is smooth.

11. The housing of claim 1, wherein the glue is an ultraviolet curing glue or a hot setting glue.

12. An electronic device, comprising:
a housing, comprising:
a main body defining a window therein and at least one glue injecting hole near the window;
a screen guard covering the window thereby defining a slit between the main body and the screen guard; and
a glue layer located in the slit to adhere the screen guard to the main body;
wherein the at least one glue injecting hole communicates with the window, and the glue layer is formed by injecting a glue into the slit from the at least one glue injecting hole.

13. The electronic device of claim 12, wherein the window is defined in an inner surface of the main body, the main body further comprises a receiving space defined in an outer surface thereof, and the screen guard is accommodated in the receiving space.

14. The electronic device of claim 13, wherein the window communicates with the receiving space, and the receiving space is larger than the window, thus a flange 114 is formed in the main body around the window; the flange supports the screen guard when the screen guard is accommodated in the receiving space.

15. The electronic device of claim 14, wherein the at least one glue injecting hole is defined in the flange.

16. The electronic device of claim 15, further comprising at least one air hole defined in the flange, the at least one air hole communicating with the slit thereby allowing air to escape from the slit.

17. The electronic device of claim 16, wherein there are two glue injecting holes and two air holes; the glue injecting holes are respectively defined near opposite corners of the window and the air holes are respectively defined near another opposite corners of the window.

18. The electronic device of claim 16, wherein the at least one glue injecting hole is substantially circular and has a diameter ranging from about 0.5 millimeter to about 1.0 millimeter.

19. The electronic device of claim 16, wherein the at least one air hole is substantially circular and has a diameter of about 0.5 millimeter.

20. The electronic device of claim 12, wherein the screen guard comprises an exterior surface and a peripheral surface, and the slit is defined between the peripheral surface and the main body in the receiving space.
